(19) United States
(12) Patent Application Publication
(10) Pub. No.: US 2006/0049437 A1
(43) Pub. Date: Mar. 9, 2006

(54) CMOS image sensors and methods for fabricating the same

(76) Inventor: Joon Hwang, Cheongju (KR)

Correspondence Address: HANLEY, FLIGHT & ZIMMERMAN, LLC, 20 N. WACKER DRIVE, SUITE 4220, CHICAGO, IL, 60606, US

(21) Appl. No.: 11/026,182

(22) Filed: Dec. 29, 2004

(30) Foreign Application Priority Data
Sep. 6, 2004 (KR) 2004-0070840

(51) Int. Cl. H01L 31/113

(52) U.S. Cl. 257/292

(57) ABSTRACT

Complementary metal-oxide semiconductor (CMOS) image sensors and methods of fabricating the same are disclosed. In one example, the method includes forming at least a first pad layer and a second pad layer on a p-type semiconductor substrate having an active area and a device dividing area defined thereon, removing the first pad layer and the second pad layer on the device dividing area, so as to expose the p-type semiconductor layer and selectively removing the exposed p-type semiconductor layer, thereby forming a trench, forming a first p-type impurity area on a portion of the p-type semiconductor substrate formed on inner walls of the trench, forming a device dividing insulating layer on an entire surface of the p-type semiconductor substrate so as to fill the trench, removing the device dividing insulating layer, so that the device dividing insulating layer remains only in the trench, and removing the second pad layer, and injecting n-type impurity ions onto the active area, thereby forming a photodiode area.

### TECHNICAL FIELD

The present disclosure relates to image sensors and, more particularly, to complementary metal-oxide semiconductor (CMOS) image sensors and methods of fabricating the same.

### BACKGROUND

Generally, an image sensor is a semiconductor device that converts an optical image to an electric signal. More specifically, a charge coupled device (CCD) is a device having a plurality of metal-oxide semiconductor (MOS) capacitors, each formed within a proximate range from one another, wherein a carrier electric charge is stored in and transmitted to each capacitor.

The charged coupled device (CCD) includes a plurality of photodiodes (PD), a plurality of vertical charge coupled devices (VCCDs), a horizontal charge coupled device (HCCD), and a sense amplifier. Herein, the photodiodes converting light signals to electric signals are aligned in a matrix form. The vertical charge coupled devices are formed between each of the photodiodes aligned in a matrix form and formed in a vertical direction, so as to transmit electric charges generated from each photodiode in a vertical direction. The horizontal charge coupled device transmits the charges transmitted from the vertical charge coupled device in a horizontal direction. The sense amplifier senses the charge transmitted in the horizontal direction and outputs the electric charges.

However, the above-described CCD is disadvantageous in that it has a complicated driving method, consumes a large amount of energy, and requires multiple photo processes, which complicate the fabrication process. A control circuit, a signal processing circuit, and an analog-to-digital (A/D) converter circuit cannot be easily integrated to the CCD, and so, the device cannot be formed in a compact size.

Recently, to overcome such disadvantages of the CCD, a CMOS image sensor is considered to be the next generation image sensor. The CMOS image sensor adopts a CMOS technology, which uses the control circuit and the signal processing circuit as peripheral devices. The CMOS technology forms MOS transistors corresponding to the number of unit pixels on a semiconductor substrate. The CMOS image sensor is a device using a switching method that can sequentially detect the output of each unit pixel by using the MOS transistors. More specifically, by forming a photodiode and MOS transistors in each of the unit pixels, the CMOS image sensor can sequentially detect the electric signals of each unit pixel using the switching method, thereby representing an image.

Additionally, because the CMOS image sensor uses the CMOS fabrication technology, the CMOS image sensor consumes less amount of energy, and has a more simple fabrication process due to a smaller number of photo processes. Furthermore, in the CMOS image sensor, a control circuit, a signal processing circuit, an A/D converter circuit, and so on, can be integrated to the CMOS image sensor chip, thereby allowing the CMOS image sensor to be formed in a compact size. Therefore, the CMOS image sensor is widely used in various applications, such as digital still cameras, digital video cameras, and so on.

Meanwhile, the CMOS image sensor can be divided into a 3-transistor (3T) type, a 4-transistor (4T) type, and a 5-transistor (5T) type CMOS image sensor depending upon the number of transistors used. The 3T type includes one photodiode and three transistors. The 4T type includes one photodiode and four transistors, and the 5T type includes one photodiode and five transistors. An equivalent circuit and a layout of a unit pixel of the 3T type CMOS image sensor will now be described in detail.

FIG. 1 illustrates an equivalent circuit diagram of a general CMOS image sensor, and FIG. 2 illustrates a layout diagram of a general CMOS image sensor.

As shown in FIG. 1, a unit pixel of the general 3T type CMOS image sensor includes one photodiode (PD) and three NMOS transistors (T1, T2, and T3). A cathode of the photodiode (PD) is connected to a drain of a first nMOS transistor (T1) and to a gate of a second nMOS transistor (T2). A source of each of the first and second transistors (T1 and T2) is connected to a power line, which provides a reference voltage (VR). A gate of the first nMOS transistor (T1) is connected to a reset line, which supplies a reset signal (RST). A source of a third nMOS transistor (T3) is connected to a drain of the second nMOS transistor (T2). A drain of the third NMOS transistor (T3) is connected to a reader circuit (not shown) through a signal line. A gate of the third NMOS transistor (T3) is connected to a column select line, which provides a select signal (SLCT). Therefore, the first nMOS transistor (T1) will be referred to as a reset transistor (Rx), the second NMOS transistor (T2) will be referred to as a driver transistor (Dx), and the third nMOS transistor (T3) will be referred to as a select transistor (Sx).

Referring to FIG. 2, in the unit pixel of the general 3T type CMOS transistor, a photodiode 20 is formed on an active area and, most particularly, on a portion of the active area having a larger width. Gate electrodes 120, 130, and 140 of three transistors overlapping one another are formed on the remaining portions of the active area. More specifically, the gate electrode 120 forms the reset transistor (Rx), the gate transistor 130 forms the driver transistor (Dx), and the gate electrode 140 forms the select transistor (Sx). Herein, impurity ions are injected in the active area 10 of each transistor, except for the lower portions of the gate electrodes 120, 130, and 140, so as to form a source/drain area of each transistor. Therefore, a power voltage Vdd is applied to the source/drain area between the reset transistor (Rx) and the driver transistor (Dx), and a source/drain area on one side of the select transistor (Sx) is connected to the reader circuit (not shown).

As described above, although not shown in the drawings, each of the gate electrodes 120, 130, and 140 is connected to each signal line. Additionally, each of the signal lines is provided with a pad on one end, so as to be connected to an external driving circuit. The signal lines provided with the pads and the following fabrication process will now be described in detail.

The related art method for fabricating a CMOS image sensor will now be described in detail. FIGS. 3A to 3F illustrate cross-sectional views showing process steps of a related art method for fabricating a CMOS image sensor, which are taken along line I-I′ of FIG. 2.

Referring to FIG. 3A, a low concentration p(−)-type epitaxial layer 2 is formed on a p-type semiconductor layer 1. Then, a pad oxide 3, a pad nitride 4, and a tetra ethyl ortho silicate (TEOS) oxide layer 5 are serially formed on the p(−)-type epitaxial layer 2. A photosensitive layer 6 is then formed on the TEOS oxide layer 5. As shown in FIG. 3B, using a mask defining an active area and a device diving area, light-exposing and developing processes are carried out to remove the photosensitive layer 6 on the device dividing area. Also, the patterned photosensitive layer 6 is used as a mask to selectively remove the pad oxide 3, the pad nitride 4, and the TEOS oxide layer 5 in the device dividing area.

Then, referring to FIG. 3C, the patterned pad oxide 3, pad nitride 4, and TEOS oxide layer 5 are used as a mask to etch the p(−)-type epitaxial layer 2 on the device dividing area to have a predetermined thickness, thereby forming a trench 7. Then, the entire photosensitive layer 6 is completely removed. Thereafter, as shown in FIG. 3D, a sacrificial oxide layer 8 is formed to have a small thickness on the entire surface of the substrate having the trench 7 formed thereon. At this point, the sacrificial oxide layer 8 is also formed on inner surfaces of the trench 7. And, the O₃ TEOS layer 9 is processed at a temperature equal to or above 1000 degrees Celsius (° C.). Furthermore, referring to FIG. 3E, a chemical mechanical polishing (CMP) process is carried out so as to remove the O₃ TEOS layer 9, except for the portion on the trench area. The patterned pad oxide 3, the pad nitride 4, and the TEOS oxide layer 5 are then removed.

Although not shown in the drawings, a p-type well and an n-type well are formed on the epitaxial layer 2 of the corresponding areas. Referring to FIG. 3F, a gate insulating layer and a conductive layer are serially formed on the entire surface of the substrate. Then, the gate insulating layer and the conductive layer are serially removed, thereby forming a gate electrode 11 and a gate insulating layer 10. Thereafter, an insulating layer is formed on the entire surface, which is then etched-back, thereby forming a sidewall insulating layer 12 on the side surfaces of the gate electrode 11.

Furthermore, p-type impurity ions and n-type impurity ions are injected in a photodiode area, thereby forming a photodiode. Then, although not shown in the drawings, an opposite conductive type impurity ions are injected in the p-type well and the n-type well, respectively, thereby forming source/drain areas on each of the transistors. Finally, a corresponding color filter layers and micro-lenses are formed on the photodiode.

However, the related art CMOS image sensor and method for fabricating the same have the following disadvantages. When forming the trench on the device dividing area, the silicon lattice structure of the epitaxial layer near the device dividing area is damaged, thereby causing a leakage of electric current in the photodiode, which deteriorates the light-receiving characteristic of the photodiode.

In addition, the surface of the photodiode area is damaged by the pad oxide removing process and the sacrifice oxide layer forming process. This causes an unnecessary interface trap to occur due to a silicon dangling bond, which also deteriorates the light-receiving characteristic of the photodiode.

### BRIEF DESCRIPTION OF THE DRAWINGS

FIG. 1 illustrates an equivalent circuit diagram of a general CMOS image sensor.

FIG. 2 illustrates a layout diagram of a general CMOS image sensor.

FIGS. 3A to 3F illustrate cross-sectional views showing process steps of a related art method for fabricating a CMOS image sensor.

FIGS. 4A to 4G illustrate cross-sectional views of a semiconductor device at various processing stages that are disclosed herein.

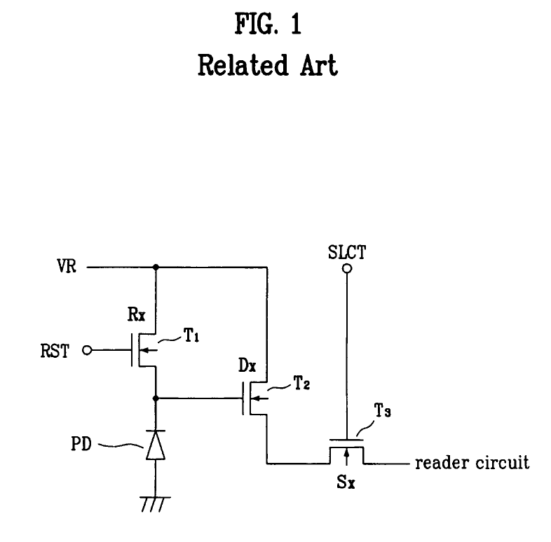

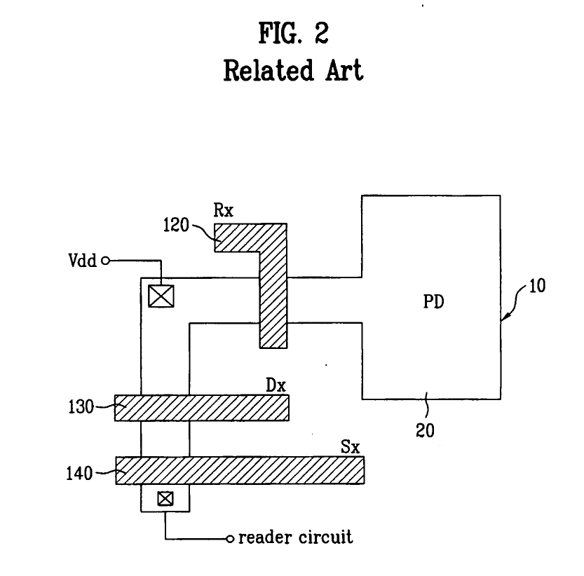

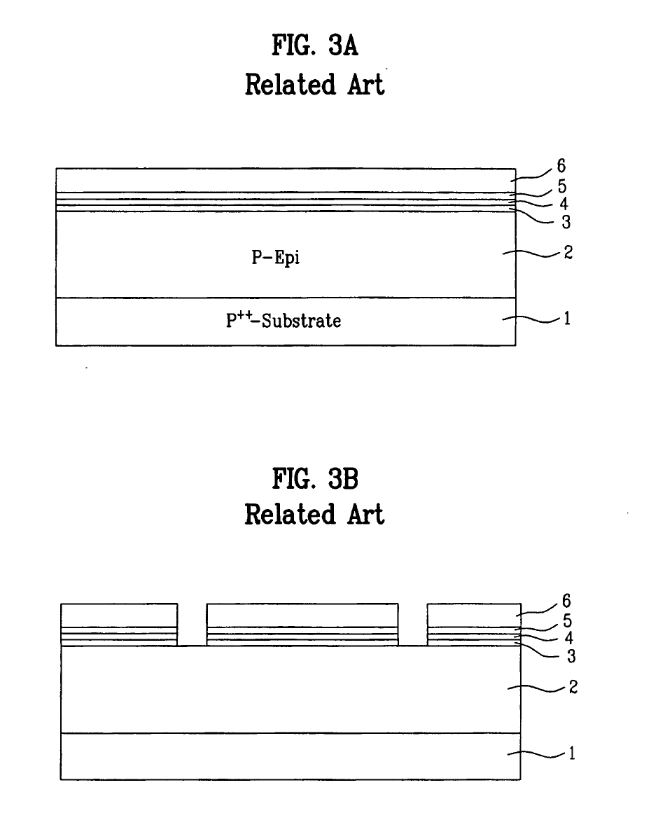

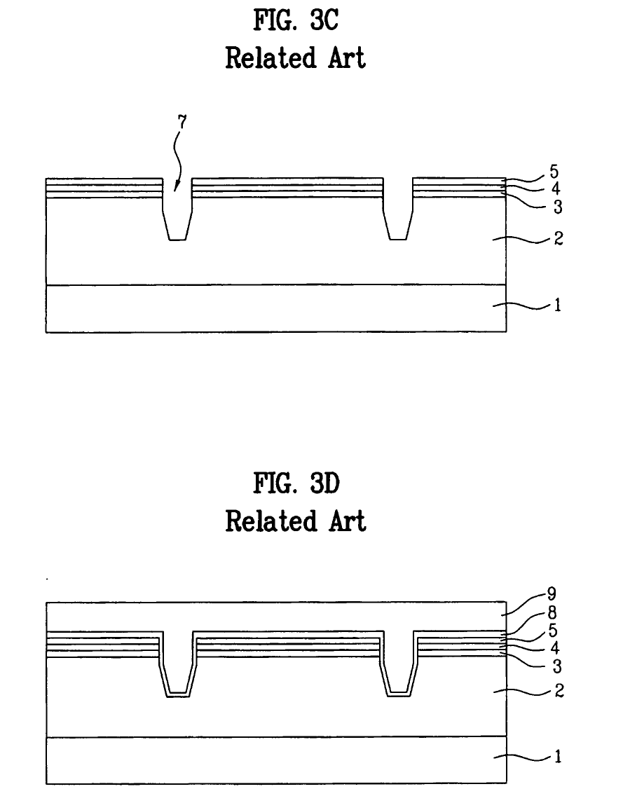

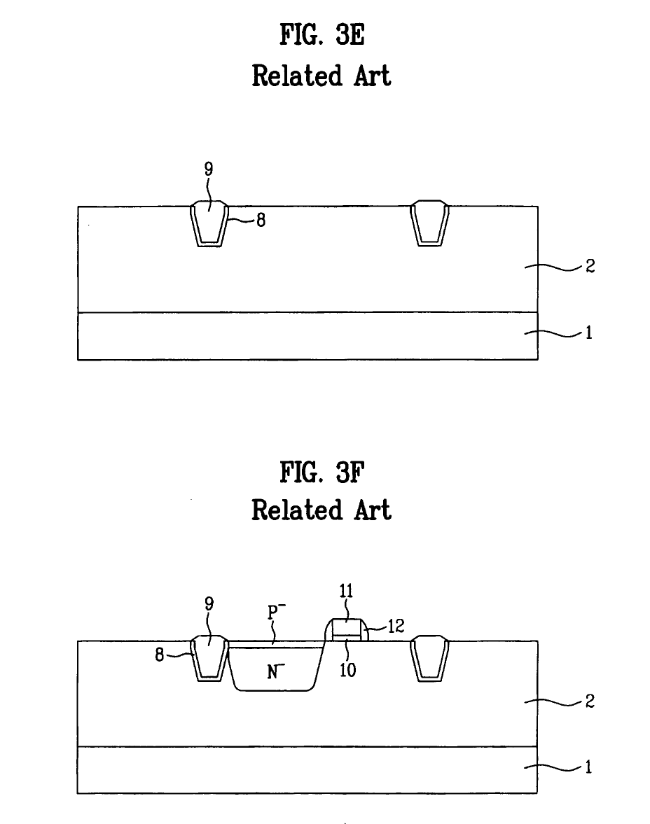

### DETAILED DESCRIPTION OF THE INVENTION

The present disclosure is suitable for a wide scope of applications. However, it is particularly suitable for reducing metal pad particles formed during a pad probing process, thereby providing a high quality image sensor having enhanced light receiving characteristics.

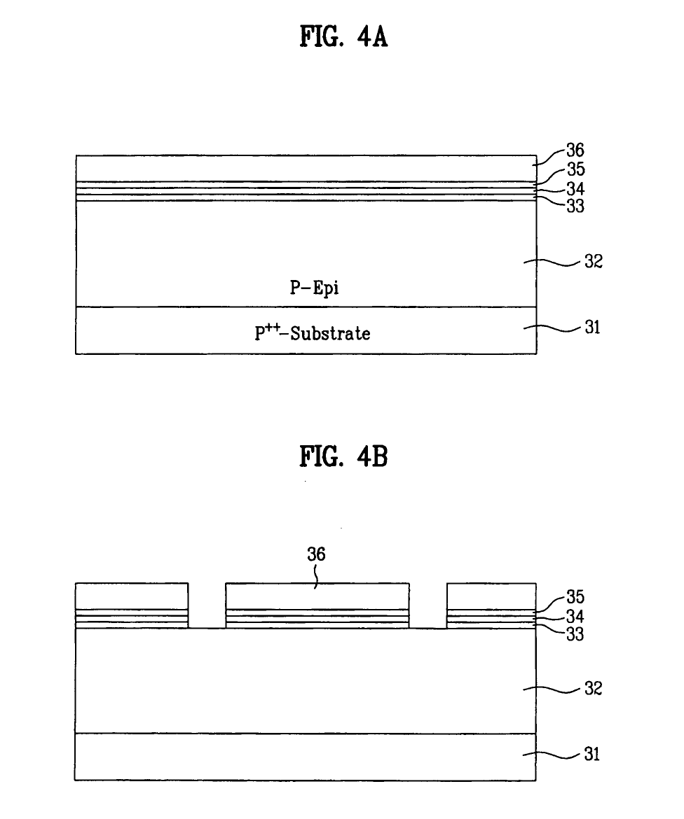

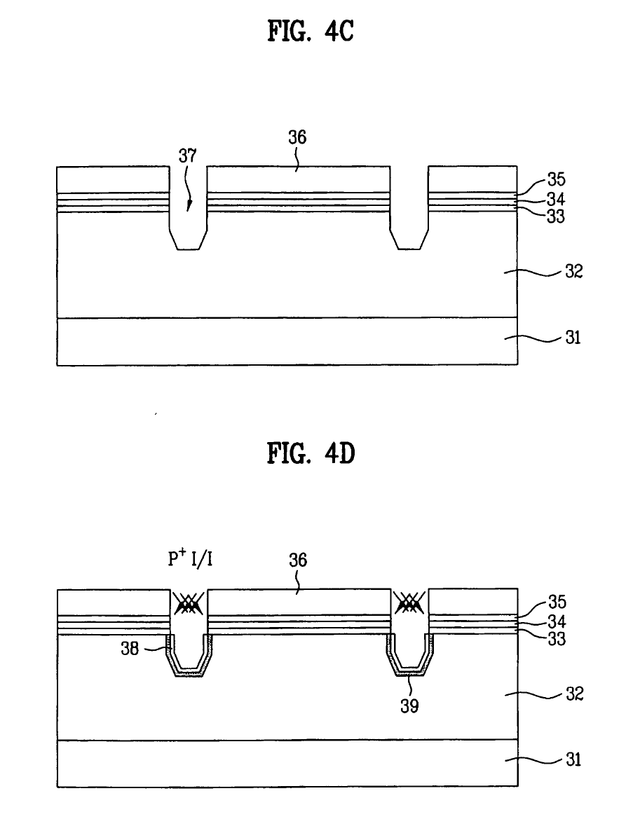

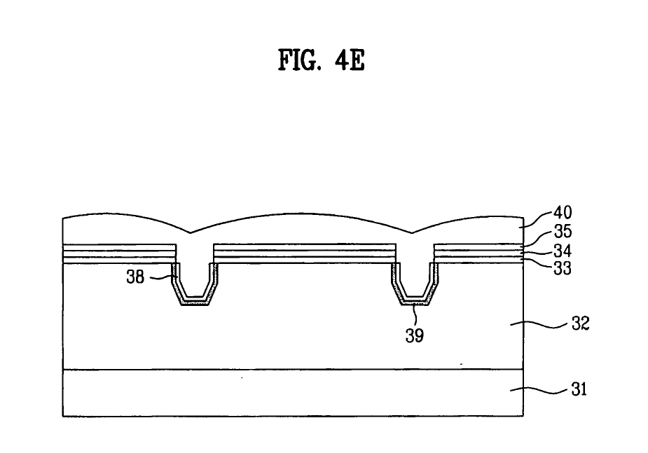

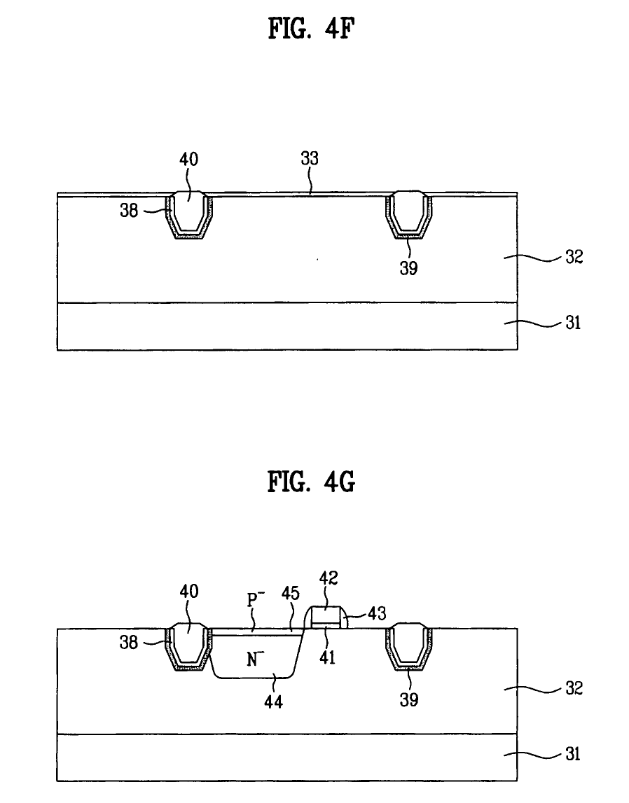

Referring to FIG. 4A, a low concentration p(−)-type epitaxial layer 32 is formed on a p-type semiconductor layer 31. Then, a pad oxide 33, a pad nitride 34, and a tetra ethyl ortho silicate (TEOS) oxide layer 35 are serially formed on the p(−)-type epitaxial layer 32. A photosensitive layer 36 is then formed on the TEOS oxide layer 35. As shown in FIG. 4B, using a mask defining an active area and a device dividing area, light-exposing and developing processes are carried out to remove the photosensitive layer 36 on the device dividing area. Also, the patterned photosensitive layer 36 is used as a mask to selectively remove the pad oxide 33, the pad nitride 34, and the TEOS oxide layer 35 in the device dividing area.

Then, referring to FIG. 4C, the patterned pad oxide 33, pad nitride 34, and TEOS oxide layer 35 are used as a mask to etch the p-type epitaxial layer 32 on the device dividing area to have a predetermined thickness, thereby forming a trench 37. Thereafter, as shown in FIG. 4D, a sacrificial oxide layer 38 is formed on inner surfaces of the trench 37 through a heat oxidation process. The sacrificial oxide layer 37 may be formed to have a small thickness. A high concentration p(+)-type impurity ions are then injected in the inner surfaces of the trench 37, thereby forming a high concentration p(+)-type impurity ion area 39. At this point, the high concentration p(+)-type impurity ions are injected using a tilted ion injection method.

Referring to FIG. 4E, a high density plasma (HDP) oxide layer 40 is deposited over the surface of the device, thereby filling the trench 37 area.

Referring to FIG. 4F, a chemical mechanical polishing (CMP) process is carried out so as to remove the HDP oxide layer 40, except for the portion on the trench 37 area. The patterned pad oxide 33, the pad nitride 34, and the TEOS oxide layer 35 are then removed. However, the pad oxide 33 still remains on the surface of the epitaxial layer 32. The pad oxide residue will be used as a buffer oxide used for ion injection in a later process.

Although not shown in the drawings, a p-type well and an n-type well are formed on the epitaxial layer 32 of the corresponding areas. As shown in FIG. 4G, the pad oxide layer 33 is removed, and a gate insulating layer and a conductive layer are serially formed on the entire surface of the substrate, which are then selectively removed, so as to form a gate electrode 42 and a gate insulating layer 41. Then, n-type impurity ions are injected in the photodiode area, so as to form a photodiode 44. A lightly doped drain (LDD) is formed in the source/drain area of the active area.

Subsequently, an insulating layer is deposited on the entire surface of the substrate, and the insulating layer is then etched-back, thereby forming a sidewall insulating layer 43 on the side surfaces of the gate electrode 42. Then, although not shown in the drawings, an opposite conductive type impurity ions are injected in the p-type well and the n-type well, respectively, thereby forming source/drain areas on each of the transistors. Further, p (P⁰)-type impurity ions are injected onto the surface of the photodiode 44, so as to form a P⁰-type impurity area 45. Thereafter, corresponding color filter layers and micro-lenses are formed on the photodiode 44 through a generally used fabrication process.

Therefore, as shown in FIG. 4G, in the structure of the photodiode of the CMOS image sensor disclosed herein, a high concentration p(+)-type impurity area is formed on the device dividing area, and a (P⁰)-type impurity area is formed on the surface of the photodiode. Because the lower surface is formed of a p(−)-type epitaxial layer, the photodiode is covered by a p-type impurity area.

As described above, the CMOS image sensor and the method for fabricating the same as disclosed herein have the following advantages. First of all, a trench is formed in the device dividing area, and p-type impurity ions are formed on the inner walls of the trench, so as to form a p(+)-type impurity area on the p(−)-type epitaxial layer around the trench. Thus, even when the silicon lattice structure of the p(−)-type epitaxial layer is damaged during the trench forming process, leakage of the electric charge does not occur in the photodiode, thereby enhancing the light-receiving characteristic of the photodiode.

In addition, after carrying out a CMP process for forming a device dividing layer, the pad oxide still remains on the surface of the photodiode, and thus, a separate sacrifice oxide layer is not required. During the p-type well and the n-type well forming processes, the pad oxide prevents the surface of the photodiode from being damaged, thereby enhancing the light-receiving characteristics of the photodiode, such as low illumination.

In one example, the disclosed CMOS image sensor may include a semiconductor substrate having a device dividing area and an active area defined thereon, a photodiode having the active area of the semiconductor substrate covered by a p-type impurity area and generating optical electric charges in accordance with a luminance of a light, and color filter layers and micro-lenses formed on a vertical line of the photodiode.

In another example, the CMOS image sensor may include a semiconductor substrate having a device dividing area and an active area defined thereon, a trench formed on the device dividing area of the semiconductor substrate, a first p-type impurity area formed on inner walls of the trench, a device dividing layer formed on the active area adjacent to the first p-type impurity area, a second p-type impurity area formed on a surface of the photodiode area, and color filter layers and micro-lenses formed on a vertical line of the photodiode.

In one example, the device dividing layer may be formed of a high density plasma (HPD) oxide layer.

An example disclosed method may include forming at least a first pad layer and a second pad layer on a p-type semiconductor substrate having an active area and a device dividing area defined thereon, removing the first pad layer and the second pad layer on the device dividing area, so as to expose the p-type semiconductor layer and selectively removing the exposed p-type semiconductor layer, thereby forming a trench, forming a first p-type impurity area on a portion of the p-type semiconductor substrate formed on inner walls of the trench, forming a device dividing insulating layer on an entire surface of the p-type semiconductor substrate so as to fill the trench, removing the device dividing insulating layer, so that the device dividing insulating layer remains only in the trench, and removing the second pad layer, and injecting n-type impurity ions onto the active area, thereby forming a photodiode area.

The first pad layer may be formed of an oxide layer, and the second pad layer may be formed of an oxide layer, or a nitride layer, and a tetra ethyl ortho silicate (TEOS) oxide layer deposited thereon.

Additionally, the example method may include, before forming a first p-type impurity area on a portion of the p-type semiconductor substrate formed on inner walls of the trench, forming a sacrifice oxide layer on inner walls of the trench. Also, the sacrificial oxide layer may be formed by using a heat oxidation process. The first p-type impurity area may be formed by injecting p-type impurity ions using a tilted ion injection method.

As noted above, the device dividing insulating layer may be formed of an HDP oxide layer. The device dividing insulating layer and the second pad layer are removed by using a chemical mechanical polishing (CMP) process.

Another method may include forming a first p-type impurity area on a surface of the photodiode area and forming a gate insulating layer and a gate electrode on the p-type semiconductor substrate, forming a source/drain area, and forming color filter layers and micro-lenses on an upper surface of the photodiode area.

This application claims the benefit of the Korean Patent Application No. 10-2004-0070840, filed on Sep. 6, 2004, which is hereby incorporated by reference as if fully set forth herein.

Although certain apparatus constructed in accordance with the teachings of the invention have been described herein, the scope of coverage of this patent is not limited thereto. On the contrary, this patent covers every apparatus, method and article of manufacture fairly falling within the scope of the appended claims either literally or under the doctrine of equivalents.

What is claimed is:

1. A complementary metal-oxide semiconductor (CMOS) image sensor, comprising:
a semiconductor substrate having a device dividing area and an active area defined thereon;
a photodiode having the active area of the semiconductor substrate covered by a p-type impurity area and generating optical electric charges in accordance with a luminance of a light; and
color filter layers and micro-lenses formed on a vertical line of the photodiode.

2. A complementary metal-oxide semiconductor (CMOS) image sensor, comprising:
a semiconductor substrate having a device dividing area and an active area defined thereon;
a trench formed on the device dividing area of the semiconductor substrate;
a first p-type impurity area formed on inner walls of the trench;
a device dividing layer formed on the active area adjacent to the first p-type impurity area;
a second p-type impurity area formed on a surface of the photodiode area; and
color filter layers and micro-lenses formed on a vertical line of the photodiode.

3. A CMOS image sensor as defined by claim 1, wherein the device dividing layer is formed of a high density plasma (HPD) oxide layer.

4. A method for fabricating a complementary metal-oxide semiconductor (CMOS) image sensor, comprising:
forming at least a first pad layer and a second pad layer on a p-type semiconductor substrate having an active area and a device dividing area defined thereon;
removing the first pad layer and the second pad layer on the device dividing area, so as to expose the p-type semiconductor layer and selectively removing the exposed p-type semiconductor layer, thereby forming a trench;
forming a first p-type impurity area on a portion of the p-type semiconductor substrate formed on inner walls of the trench;
forming a device dividing insulating layer on an entire surface of the p-type semiconductor substrate so as to fill the trench;
removing the device dividing insulating layer, so that the device dividing insulating layer remains only in the trench, and removing the second pad layer; and
injecting n-type impurity ions onto the active area, thereby forming a photodiode area.

5. A method as defined by claim 4, wherein the first pad layer is formed of an oxide layer, and wherein the second pad layer is formed of an oxide layer, or a nitride layer, and a tetra ethyl ortho silicate (TEOS) oxide layer deposited thereon.

6. A method as defined by claim 4, further comprising, before forming a first p-type impurity area on a portion of the p-type semiconductor substrate formed on inner walls of the trench, forming a sacrifice oxide layer on inner walls of the trench.

7. A method as defined by claim 6, wherein the sacrifice oxide layer is formed by using a heat oxidation process.

8. A method as defined by claim 4, wherein the first p-type impurity area is formed by injecting p-type impurity ions using a tilted ion injection method.

9. A method as defined by claim 4, wherein the device dividing insulating layer is formed of a high density plasma (HDP) oxide layer.

10. A method as defined by claim 4, wherein the device dividing insulating layer and the second pad layer are removed by using a chemical mechanical polishing (CMP) process.

11. A method as defined by claim 4, further comprising forming a first p-type impurity area on a surface of the photodiode area.

12. A method as defined by claim 4, further comprising:
forming a gate insulating layer and a gate electrode on the p-type semiconductor substrate;
forming a source/drain area; and
forming color filter layers and micro-lenses on an upper surface of the photodiode area.
